(19) United States
(12) Patent Application Publication
(10) Pub. No.: US 2024/0150590 A1
(43) Pub. Date: May 9, 2024

(54) COATED SUBSTRATES FOR ELECTRONIC DEVICES

(71) Applicant: Hewlett-Packard Development Company, L.P., Spring, TX (US)

(72) Inventors: Kuan-Ting WU, Taipei (TW); Yong-Jun LI, Shanghai, Zhangjiang (CN); Chi Hao CHANG, Taipei (TW); Xiao-Jun ZHU, Chongqing, Zhongqing (CN)

(21) Appl. No.: 18/281,502

(22) PCT Filed: Mar. 18, 2021
(86) PCT No.: PCT/US2021/022922

§ 371 Date: Sep. 11, 2023

(51) Int. Cl. C09D 5/16; C09D 5/00; C09D 5/03; C09D 7/40; C09D 7/42; C09D 7/61; C09D 7/63; C09D 7/65; G06F 1/18; H05K 5/04

(52) U.S. Cl. CPC C09D 5/1637; C09D 5/002; C09D 5/035; C09D 5/1625; C09D 7/42; C09D 7/61; C09D 7/63; C09D 7/65; C09D 7/67; G06F 1/181; H05K 5/04

(57) ABSTRACT

A coated substrate for an electronic device can include a substrate, a basecoat layer on the substrate, and an anti-fingerprint topcoat layer on the basecoat layer. The substrate can include a metal or metal alloy. The basecoat layer can include pigment particles and a first one-part thermally cured polymeric resin. The anti-fingerprint topcoat layer can include a second one-part thermally cured polymeric resin and an anti-fingerprint material. The anti-fingerprint material can include a fluoropolymer, a silane, or a combination thereof. The basecoat layer can be cured before applying the anti-fingerprint topcoat layer on the basecoat layer.

A variety of substrates can be used in electronic devices, for example as housings, cases, support structures, and so on. However, many substrate materials can be adversely affected in a natural environment, such as via corrosion, wear, etc. As such, these substrates are often coated to impart corrosion resistance, electrical resistance, wear resistance, decoration, and a variety of other desirable properties. Coatings can be applied via a variety of techniques. However, it can be difficult to achieve all desired characteristics for a coated substrate.

### BRIEF DESCRIPTION OF THE DRAWINGS

FIG. 1 is a cross-sectional view of an example coated substrate in accordance with examples of the present disclosure;

FIG. 2 is another cross-sectional view of an example coated substrate in accordance with examples of the present disclosure;

FIG. 3 is yet another cross-sectional view of an example coated substrate in accordance with examples of the present disclosure;

FIG. 4 is another cross-sectional view of an example coated substrate in accordance with examples of the present disclosure;

FIG. 5 is another cross-sectional view of an example coated substrate in accordance with examples of the present disclosure;

FIG. 6 is a flowchart illustrating an example method of making a coated substrate for an electronic device in accordance with examples of the present disclosure; and

FIG. 7 is a schematic view of an example electronic device in accordance with examples of the present disclosure.

### DETAILED DESCRIPTION

The present disclosure describes coated substrates for electronic devices, methods of making coated substrates for electronic devices, and electronic devices that include the coated substrates. In one example, a coated substrate for an electronic device includes a substrate that includes metal or metal alloy. A basecoat layer is on the substrate. The basecoat layer includes pigment particles and a first one-part thermally cured polymeric resin. An anti-fingerprint topcoat layer is on the basecoat layer. The anti-fingerprint topcoat layer includes a second one-part thermally cured polymeric resin and an anti-fingerprint material. The anti-fingerprint material includes a fluoropolymer, a silane, or a combination thereof. The basecoat layer is cured before applying the anti-fingerprint topcoat layer on the basecoat layer. In some examples, the metal or metal alloy can include aluminum, magnesium, lithium, titanium, or an alloy thereof. The substrate can also include a passivation layer, a micro-arc oxidation layer, or both on a surface of the substrate. In other examples, the pigment particles can include carbon black, graphene, titanium dioxide, clay, mica, barium sulfate, calcium carbonate, metallic powder, aluminum oxide, or a combination thereof. In further examples, the first one-part thermally cured polymeric resin or the second one-part thermally cured polymeric resin or both can include urethane acrylic, acrylic, hydroxyl acrylic, alkyd, polyester, or a combination thereof. In certain examples, the anti-fingerprint topcoat layer can have a thickness from about 10 μm to about 25 μm. In still further examples, the anti-fingerprint topcoat layer can also include a matting compound, wherein the matting compound includes silica nanoparticles, titania nanoparticles, alumina nanoparticles, or a combination thereof. In some other examples, the coated substrate can include a primer layer on the substrate and under the basecoat layer. The primer layer can include a third one-part thermally cured polymeric resin. In still other examples, the coated substrate can include a powder coat layer on the substrate and under the primer layer. The powder coat layer can include a polymer including epoxy, poly(vinyl chloride), polyamide, polyester, polyurethane, acrylic, polyphenylene ether, or a combination thereof, and a high aspect ratio filler. In certain examples, a surface of the topcoat layer can have a water contact angle from about 95° to about 110°.

The present disclosure also describes methods of making coated substrates for electronic devices. In one example, a method of making a coated substrate for an electronic device includes applying a waterborne one-part basecoat composition on a substrate to form a basecoat layer. The basecoat composition includes a first thermally curable polymeric resin and pigment particles. The basecoat layer is heated to cure the first thermally curable polymeric resin. A waterborne one-part topcoat composition is then applied onto the basecoat layer to form a topcoat layer. The topcoat composition includes a second thermally curable polymeric resin and an anti-fingerprint material. The anti-fingerprint material includes a fluoropolymer, a silane, or a combination thereof. The topcoat layer is heated to cure the second thermally curable polymeric resin. In some examples, the method can also include applying a waterborne one-part primer composition onto the substrate and curing the primer composition to form a primer layer before applying the basecoat composition. The primer composition can include a third thermally curable polymeric resin. In other examples, the basecoat composition and the topcoat composition can have a volatile organic compound content of 200 g/L or less.

The present disclosure also describes electronic devices that include the coated substrates. In one example, an electronic device includes a housing carrying electronic components of the electronic device. The housing includes a coated substrate, which includes a substrate including a metal or metal alloy. A basecoat layer is on the substrate. The basecoat layer includes pigment particles and a first one-part thermally cured polymeric resin. An anti-fingerprint topcoat layer is on the basecoat layer. The anti-fingerprint topcoat layer includes a second one-part thermally cured polymeric resin and an anti-fingerprint material. The anti-fingerprint material includes a fluoropolymer, a silane, or a combination thereof. The basecoat layer is cured before applying the anti-fingerprint topcoat layer on the basecoat layer. In some examples, the first one-part thermally cured polymeric resin or the second one-part thermally cured polymeric resin or both can include urethane acrylic, acrylic, hydroxyl acrylic, alkyd, polyester, or a combination thereof. The topcoat composition can also include a matting compound. The matting compound can include silica nanoparticles, titania nanoparticles, alumina nanoparticles, or a combination thereof. In further examples, the electronic device can include a display, a personal computer, a laptop computer, a tablet, a media player, a smart device, a keyboard, or a combination thereof.

In addition to the examples described above, the coated substrates, methods of making coated substrates and the electronic devices will be described in greater detail below. It is also noted that when discussing the coated substrates, methods of making coated substrates, and electronic devices described herein, these relative discussions can be considered applicable to the other examples, whether or not they are explicitly discussed in the context of that example. Thus, for example, in discussing a basecoat layer related to a coated substrate, such disclosure is also relevant to and directly supported in the context of the methods of making coated substrates and electronic devices described herein, and vice versa.

### Coated Substrates for Electronic Devices

The coated substrates described herein can be used in enclosures for electronic devices, such as laptop computers, smartphones, tablet computers, and so on. The particular coatings described herein can provide a finish with good hardness and useful anti-fingerprint and anti-smudge properties. In some examples, the coated substrate can have a pencil hardness in the range of 2H to 4H as measured using a pencil hardness tester. In further examples, the coated substrate can have a high water-contact angle in the range of 95° to 110°, which can correspond to good anti-fingerprint and anti-smudge properties.

The coated substrates described herein can also utilize waterborne one-part coating compositions. This can simplify the coating process, making the coatings easier to use. For example, one-part coating compositions, also referred to as “1 K” coating compositions, can be thermally curable by heating above a specific curing temperature. These coating compositions can remain uncured for a long time, in some cases indefinitely, if the temperature of the composition is kept below the curing temperature. This can make the one-part coating compositions easier to use than two-part, or “2K,” coating compositions. Two-part compositions can have a relatively short pot life because the curing process can begin when the two parts of the composition are mixed together. Additionally, two-part coating compositions are often used with in-line mixing equipment that adds to the cost of the coating process. Alternatively, if two-part coating compositions are used without in-line mixing equipment, then a significant amount of the coating composition is often wasted because an excess of the two parts is mixed and some of the mixed composition cures without being used. Two-part coating compositions can also cause blocking of pipes due to curing within the pipes unless the pipes are carefully cleaned before the composition becomes cured. Cleaning pipes and repairing blocked pipes can increase the downtime of the coating process. Therefore, the one-part coating compositions described herein can provide for a lower cost coating process that is easier to use, with less waste, compared to two-part coating compositions.

The coating compositions described herein can also be waterborne, meaning that a majority of the solvent content in the compositions is water. In some examples, water can make up 50 wt % or more of the coating compositions based on the total weight of the coating compositions. The amount of organic solvent in the coating compositions can be relatively small. In some examples, organic solvent can make up 20 wt % or less of the coating compositions based on the total weight of the coating compositions. The waterborne coating compositions can have low volatile organic compound (VOC) content. Therefore, the amount of volatile organic material given off as fumes from the coating compositions can be small. This can benefit the environment, as the coating compositions produce less air pollution than high VOC coatings. The waterborne coatings can also be safer and healthier for workers performing the coating process because the workers can be exposed to a smaller amount of organic fumes.

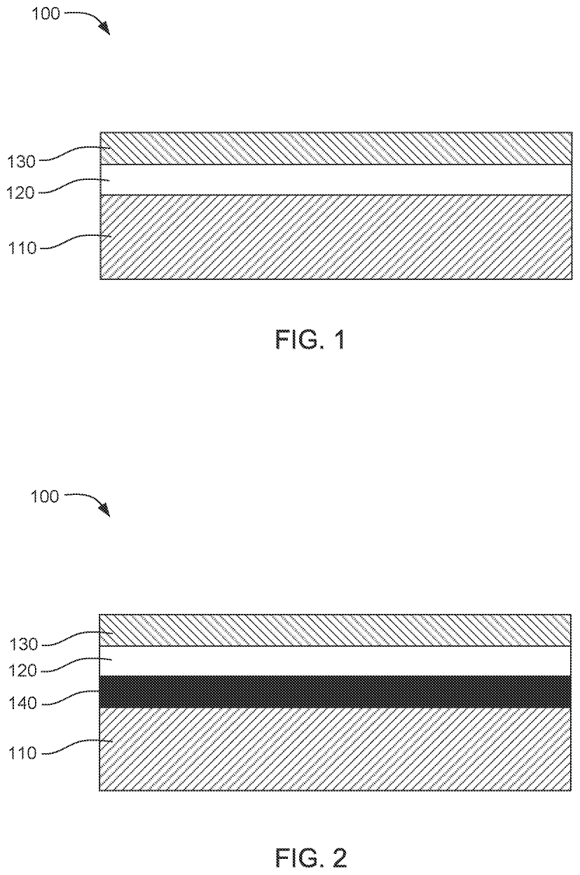

With this description in mind, FIG. 1 shows a schematic view of one example coated substrate 100 in accordance with examples of the present disclosure. In this example, the coated substrate includes a substrate 110 that includes a metal or metal alloy. A basecoat layer 120 is on the substrate. This basecoat layer can include pigment particles and a first one-part thermally cured polymeric resin. An anti-fingerprint topcoat layer 130 is on the basecoat layer. The anti-fingerprint topcoat layer can include a second one-part thermally cured polymeric resin and an anti-fingerprint material. The anti-fingerprint material can include a fluoropolymer, a silane, or a combination thereof. The basecoat layer can be cured before applying the anti-fingerprint topcoat layer on the basecoat layer.

FIG. 2 shows another example coated substrate 100. This example also includes a substrate 110 that includes metal or a metal alloy. However, in this example, a primer layer 140 is applied on the substrate before the basecoat layer 120. Thus, the primer layer is under the basecoat layer. The primer layer can include a third one-part thermally cured polymeric resin. In certain examples, the primer layer can be cured before applying the basecoat layer on the primer layer. This example also includes a topcoat layer 130 on the basecoat layer. The topcoat layer can again include an anti-fingerprint material such as a fluoropolymer, a silane, or a combination thereof.

Additional coating layers can also be included in the coated substrates in some examples. In certain examples, a powder coat can be included in the coated substrate. Powder coat layers can include materials such as a high aspect ratio filler with a polymer such as epoxy, poly(vinyl chloride), polyamide, polyester, polyurethane, acrylic, polyphenylene ether, or combinations thereof. The powder coat layer can be added on the substrate, or on the primer layer, or on the basecoat layer, in various examples. In certain examples, the powder coat layer can be applied on the substrate and under the primer layer. In other examples, the powder coat layer can be applied on the substrate and under the basecoat layer when no primer layer is present.

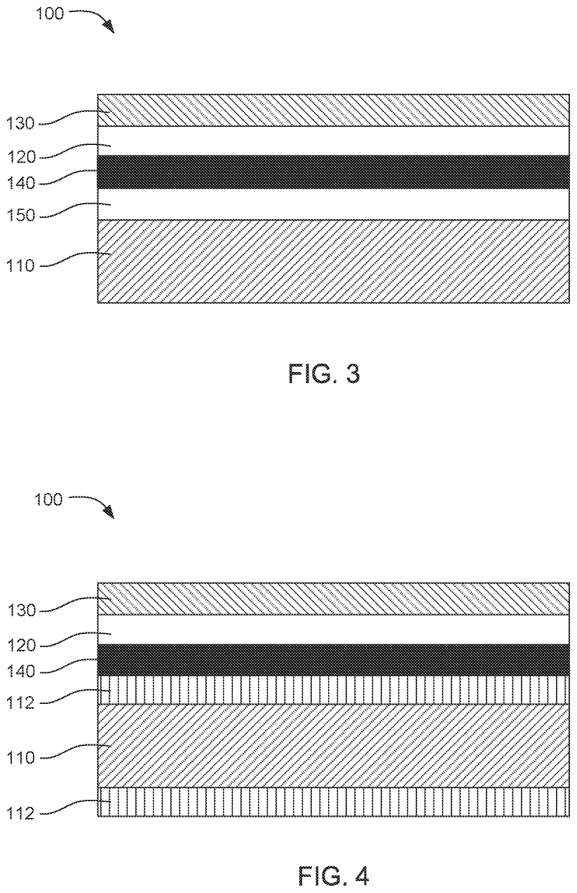

FIG. 3 shows another example coated substrate 100 that includes a powder coat layer 150 on the substrate 110. A primer layer 140 is applied on the powder coat layer. A basecoat layer 120 is applied on the primer layer, and an anti-fingerprint topcoat layer 130 is applied on the basecoat layer. These layers can include the various ingredients described above. Additional examples of ingredients in these layers are also described in more detail below.

As explained above, in some examples the basecoat layer can be cured before the topcoat layer is applied. In particular, a topcoat composition can be applied on the basecoat layer after the basecoat layer has been cured. The topcoat composition can also be cured to form a cured topcoat layer. Thus, these layers can be cured independently. Curing the basecoat layer and the topcoat layer independently can result in discrete layers, without a significant amount of interpenetration of the topcoat material into the basecoat layer, or of the basecoat material into the topcoat layer. If the topcoat composition were to be applied before the basecoat layer was cured, then some interpenetration and mixing of the materials in these two layers may occur. However, curing the individual layers before applying the following layer can result in a clear boundary between the cured layers. In some examples, a primer composition can be applied on the substrate and cured before the basecoat composition is applied. In further examples, curing the layers can include partially curing the layers or fully curing the layers before applying the following layer. In certain examples, the individual layers can be fully cured before the following layer is applied.

The substrates that are used in the coated substrate described herein can include a metal or metal alloy. In some examples, the metal can be a light metal. In certain examples, protective layers can be formed on one or both sides of the metal substrate. The protective layers can include a passivation layer or a micro-arc oxidation layer. Passivation layers can protect the metal substrate from corrosion or other chemical reactions in some examples. In some cases, passivation layers can be formed by treating the metal substrate with a passivation chemical such as a molybdate, vanadate, phosphate, chromate, stannate, manganese salt, or others. FIG. 4 shows an example coated substrate 100 that includes a metal substrate 110. The substrate is treated with passivation chemicals to form passivation layers 112 on both sides of the metal substrate. A primer layer 140 is formed over the passivation layer on one side of the substrate. A basecoat layer 120 is applied over the primer layer. An anti-fingerprint topcoat layer 130 is then applied over the basecoat layer. As explained above, the primer layer, basecoat layer, and anti-fingerprint topcoat layer can be cured individually in some examples. In particular, the primer layer can be cured before applying the basecoat layer and the basecoat layer can be cured before applying the topcoat layer.

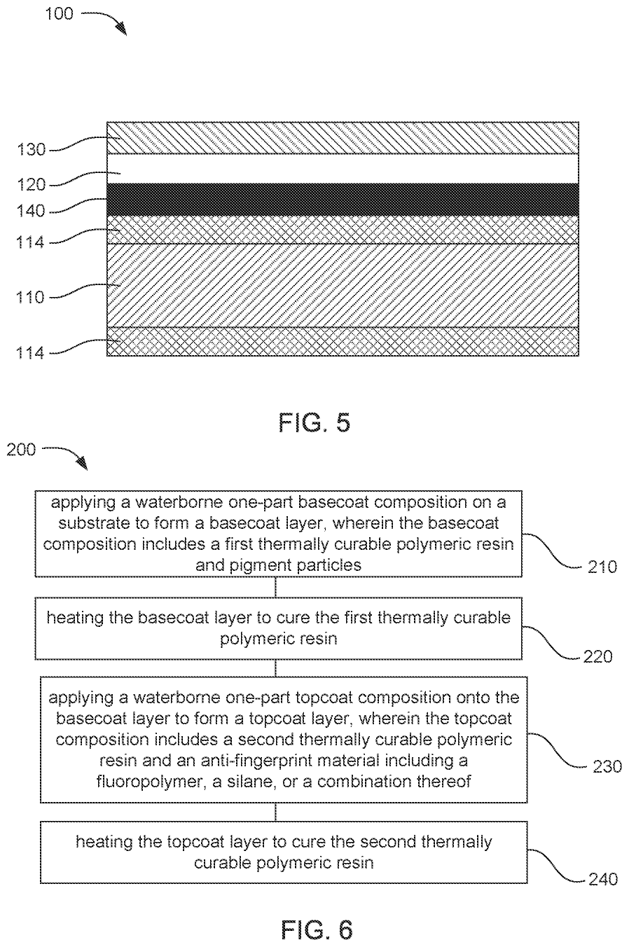

Micro-arc oxidation is another treatment that can be applied to certain metal substrates. In this process, a high voltage is applied to the metal substrate while in an electrolyte solution. The surface of the metal substrate becomes oxidized, forming a protective oxide layer. In some examples, a metal substrate can be treated with micro-arc oxidation before the coatings described herein are applied. FIG. 5 shows another example coated substrate 100 that includes a metal substrate 110 with micro-arc oxidation layers 114 on both sides of the substrate. A primer layer 140 is applied to one side of the substrate over the micro-arc oxidation layer. A base coat layer 120 is applied over the primer layer. An anti-fingerprint topcoat layer 130 is applied over the basecoat layer. The primer layer, base coat layer, and anti-fingerprint topcoat layer can include the ingredients described above.

### Methods of Making Coated Substrates for Electronic Devices

The present disclosure also describes methods of making coated substrates for electronic devices. These methods can include providing a substrate and applying coating layers to the substrate as described herein. In some examples, the methods can include applying a basecoat layer to the substrate and then applying an anti-fingerprint topcoat layer over the basecoat layer. The basecoat layer can be cured before applying the anti-fingerprint topcoat layer.

FIG. 6 is a flowchart of a particular example method 200 of making a coated substrate for an electronic device. This method includes: applying a waterborne one-part basecoat composition on a substrate to form a basecoat layer, wherein the basecoat composition includes a first thermally curable polymeric resin and pigment particles 210; heating the basecoat layer to cure the first thermally curable polymeric resin 220; applying a waterborne one-part topcoat composition onto the basecoat layer to form a topcoat layer, wherein the topcoat composition includes a second thermally curable polymeric resin and an anti-fingerprint material including a fluoropolymer, a silane, or a combination thereof 230; and heating the topcoat layer to cure the second thermally curable polymeric resin 240.

Methods of making coated substrates can also include forming a primer layer on the substrate and under the basecoat layer. For example, a waterborne one-part primer composition can be applied onto the substrate. The primer composition can then be cured to form a primer layer. The primer composition can include a third thermally curable polymeric resin.

As mentioned above, the basecoat composition, anti-fingerprint topcoat composition, and primer composition can be waterborne coating compositions. Water can make up a majority of the solvent content of these compositions. In some examples, the basecoat composition, anti-fingerprint topcoat composition, and primer composition can include water in an amount from about 50 wt % to about 70 wt % with respect to the total weight of the compositions. These compositions can also include organic co-solvents in some examples. The amount of organic co-solvent can be less than the amount of water in the compositions. In some examples, these compositions can include an organic co-solvent in an amount from about 10 wt % to about 20 wt % with respect to the total weight of the compositions. These compositions can have a low volatile organic compound content. In some examples, the compositions can have a volatile organic compound content of about 200 g/L or less. In other examples, the compositions can have a volatile organic compound content of about 160 g/L or less.

The coating compositions can be applied using a variety of application processes, such as spin coating, dipping, spraying, spreading, and so on. After applying the compositions, the coatings can be individually cured using a curing process. The curing process can include heating the coatings to cure the thermally curable resins in the coatings. In various examples, the coating compositions can be cured by heating the coating layers to a curing temperature for a curing time. In certain examples, the curing temperature can be from about 60° C. to about 200° C., or from about 80° C. to about 150° C., or from about 100° C. to about 150° C., or from about 80° C. to about 100° C. The curing time can be from about 1 minute to about 60 minutes, or from about 3 minutes to about 40 minutes, or from about 3 minutes to about 20 minutes, or from about 3 minutes to about 15 minutes, or from about 15 minutes to about 40 minutes.

In further examples, methods can include forming additional coating layers on the substrate, such as passivation layers, micro-arc oxidation layers, and powder coat layers. In one example, a method of making a coated substrate can include forming a passivation layer on a metal or metal alloy substrate. A basecoat layer and an anti-fingerprint topcoat layer can then be formed over the passivation layer. In further examples, a primer layer can be formed on the passivation layer and under the basecoat layer.

In a particular example, a passivation layer can be formed on a metal or metal alloy substrate by immersing the substrate in a bath including a passivation chemical. Some examples of passivation chemicals can include molybdates, vanadates, phosphates, chromates, stannates, and manganese salts. The concentration of the passivation chemical in the bath can be from about 3 wt % to about 15 wt %, or from about 3 wt % to about 10 wt %, or from about 10 wt % to about 15 wt %. The passivation treatment can be performed for a time from about 20 seconds to about 180 seconds, or from about 30 seconds to about 180 seconds, or from about 60 seconds to about 180 seconds. The resulting passivation layer can have a thickness from about 1 μm to about 5 μm.

In another example, a method of making a coated substrate for an electronic device can include forming a micro-arc oxidation layer on a metal or metal alloy substrate. A basecoat layer and an anti-fingerprint layer can then be formed over the micro-arc oxidation layer. In further examples, a primer layer can be formed on the micro-arc oxidation layer and under the basecoat layer.

In a particular example, a micro-arc oxidation layer can be formed by applying a voltage to a metal or metal alloy substrate submerged in an electrolyte bath. In some examples, the voltage applied can be from about 150 V to about 550 V. Chemicals that can be included in the electrolyte bath can include sodium silicate, metal phosphate, potassium fluoride, potassium hydroxide, sodium hydroxide, fluorozirconate, sodium hexametaphosphate, sodium fluoride, ferric ammonium oxalate, phosphoric acid salts, graphite powder, silicon dioxide powder, aluminum oxide powder, metal powder, or combinations thereof. The chemicals can be mixed with water at a concentration of about 0.3 wt % to about 15 wt % of the chemical in water. In some examples, the pH of the electrolyte bath can be from about 8 to about 13. The light metal substrate can be immersed in the electrolyte bath and the voltage can be applied for a time period from about 2 minutes to about 25 minutes, or from about 3 minutes to about 25 minutes, or from about 6 minutes to about 25 minutes. The temperature of the electrolyte bath can be from about 10° C. to about 45° C. In further examples, the thickness of the micro-arc oxidation layer can be from about 3 μm to about 15 μm.

In yet another example, a method of making a coated substrate for an electronic device can include forming a powder coat layer. In some examples, the powder coat layer can be formed over the substrate or over a passivation layer on the substrate or over a micro-arc oxidation layer on the substrate. The powder coat layer can be formed under other coating layers, such as under a basecoat layer or under a primer layer. The powder coat layer can include a high aspect ratio filler such as talc, clay, graphene, or high aspect ratio pigments. The high aspect ratio filler can be bound together by a polymer such as epoxy, poly(vinyl chloride), polyamide, polyester, polyurethane, acrylic, polyphenylene ether, or others. In some examples, the polymer and high aspect ratio filler can be applied using an electrostatic application process. The powder coat layer can be cured by heating to a curing temperature from about 120° C. to about 190° C., or from about 150° C. to about 190° C. The thickness of the powder coat layer can be from about 20 μm to about 60 μm, or from about 30 μm to about 60 μm, or from about 20 μm to about 40 μm.

### Electronic Devices

The coated substrates described herein can be used in a variety of electronic devices. For example, the substrates can be used as a housing, a cover, a frame, a support structure, the like, or a combination thereof for a variety of electronic devices. For example, the coated substrates can be used with a display, a personal computer, a laptop computer, a tablet, a media player, a smart device, a keyboard, the like, or a combination thereof.

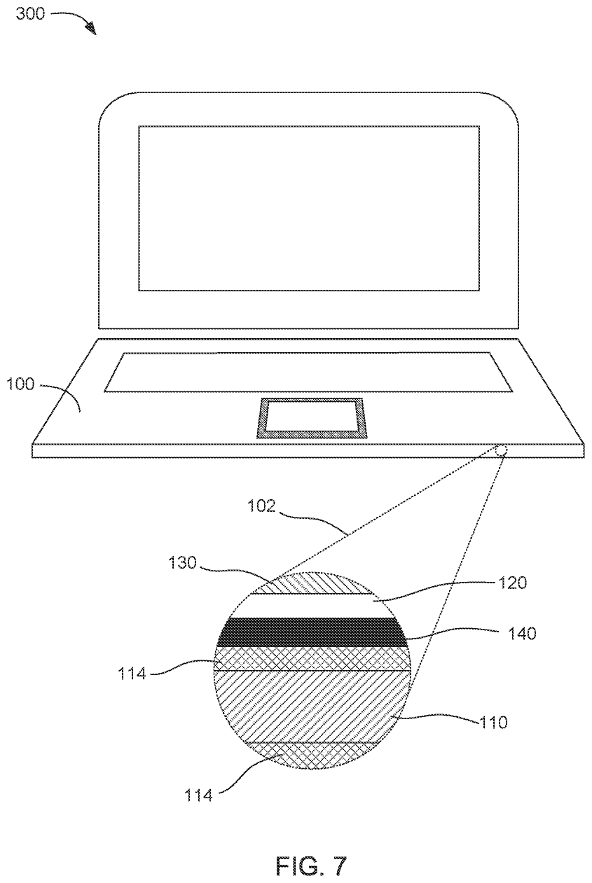

One non-limiting example of an electronic device in accordance with the present disclosure is presented in FIG. 7. In this example, the electronic device 300 is a laptop computer. A coated metal substrate 100 forms the housing of the laptop computer. A magnified cross-sectional view 102 of the coated metal substrate is also shown. The coated metal substrate includes a metal substrate 110 with micro-arc oxidation layers 114 on both sides. A primer layer 140, a base coat layer 120, and an anti-fingerprint topcoat layer 130 are applied to the substrate.

### Substrates

In some examples, the substrate can include a metal or metal alloy. In some examples, the substrate can be made up fully of a metal or metal alloy. In other examples, the substrate can be a composite of a metal or metal alloy with another material. Some additional materials that can be used in composites can include plastic, carbon fiber, glass, and combinations thereof. In certain examples, the substrate can include a light metal such as aluminum, magnesium, titanium, lithium, niobium, or an alloy thereof. In some examples, alloys of these metals can include additional metals, such as bismuth, copper, cadmium, iron, thorium, strontium, zirconium, manganese, nickel, lead, silver, chromium, silicon, tin, gadolinium, yttrium, calcium, antimony, zinc, cerium, lanthanum, or others.

In further examples, the substrate can include carbon fiber. In particular, the substrate can be a carbon fiber composite. The carbon fiber composite can include carbon fibers in a plastic material such as a thermoset resin or a thermoplastic polymer. Non-limiting examples of the polymer can include epoxies, polyesters, polyacrylic, polycarbonate, vinyl esters, and polyamides.

In various examples, the substrate can be formed by molding, casting, machining, bending, working, or another process. In certain examples, the substrate can be a housing or chassis for an electronic device that is milled from a single block of metal or metal alloy. In other examples, an electronic device housing can be made from multiple panels.

The substrate is not particularly limited with respect to thickness. However, when used as a panel for an electronic device, such as for a housing or chassis, the thickness of the substrate chosen, the density of the material (for purposes of controlling weight, for example), the hardness of the material, the malleability of the material, the material aesthetic, etc., can be selected as appropriate for a specific type of electronics device, e.g., lightweight materials and thickness chosen for housings where lightweight properties may be commercially competitive, heavier more durable materials chosen for housings where more protection may be useful, etc. To provide some examples, the thickness of the substrate can be from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about mm, though thicknesses outside of these ranges can be used.

### Passivation Layers

In some examples, the substrate can be treated with a passivation treatment to form a passivation layer before other layers are coated onto the substrate. Passivation can be particularly useful for substrates made of light metals. In some cases, the passivation treatment can include immersing the substrate in a bath including a passivation chemical. Some examples of passivation chemicals can include molybdates, vanadates, phosphates, chromates, stannates, and manganese salts. In certain examples, the concentration of the passivation chemical in the bath can be from about 3 wt % to about 15 wt %. In other examples, the concentration can be from about 3 wt % to about 6 wt %, or from about 3 wt % to about 9 wt %, or from about 8 wt % to about 12 wt %, or from about 8 wt % to about 15 wt %. The remainder of the bath can be water. In further examples, the passivation treatment can be performed for a time from about 20 seconds to about 120 seconds. In other examples, the passivation treatment can be performed for a time from about 20 seconds to about 60 seconds, or from about 60 seconds to about 120 seconds, or from about 30 seconds to about 90 seconds. The resulting passivation layer can have a thickness from about 1 μm to about 5 μm in some examples. In other examples, the passivation layer thickness can be from about 1 μm to about 3 μm, or from about 3 μm to about 5 μm, or from about 2 μm to about 4 μm.

In other examples, the passivation chemicals can include a chelating agent. Non-limiting examples of chelating agents can include ethylenediaminetetraacetic acid (EDTA), ethylenediamine, nitrilotriacetic acid (NTA), diethylenetriaminepenta(methylenephosphonic acid) (DTPPH), nitrilotris(methylenephosphonic acid) (NTMP), 1-hydroxyethane-1,1-diphosphonic acid (HEDP), phosphoric acid, the like, or a combination thereof. In further examples, the passivation layer can include an organic acid in combination with aluminum, nickel, chromium, tin, indium, zinc, the like, or a combination thereof. Various combinations of the previously recited materials can also be employed.

### Micro-Arc Oxidation Layers

The substrate can be treated with a micro-arc oxidation treatment to form a micro-arc oxidation layer in some examples. This treatment is also particular useful for light metal substrates. Micro-arc oxidation, also referred to as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 0.3 wt % to about 15 wt % electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be 150 V or higher, such as about 150 V to about 550 V, about 250 V to about 550 V, about 250 V to about 500 V, or about 200 V to about 300 V. Temperatures can be from about 10° C. to about 45° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 μm or more. In some examples the oxide layer can have a thickness from about 2 μm to about 15 μm, from about 2 μm to about 12 μm, or from about 2 μm to about 10 μm, or from about 3 μm to about 10 μm, or from about 4 μm to about 7 μm. The oxide layer can, in some instances, enhance the mechanical, wear, thermal, dielectric, and corrosion properties of the substrate. The electrolyte solution can include a variety of electrolytes, such as a solution of potassium hydroxide. In certain examples, the electrolyte solution can include sodium silicate, metal phosphate, potassium fluoride, potassium hydroxide, sodium hydroxide, fluorozirconate, sodium hexametaphosphate, sodium fluoride, ferric ammonium oxalate, phosphoric acid salts, graphite powder, silicon dioxide powder, aluminum oxide powder, metal powder, or combinations thereof. In some examples, the substrate can include a micro-arc oxidation layer on one side, or on both sides.

### Primer Layers

A primer layer can be applied to the substrate in some examples. The primer layer can be formed by applying a liquid primer composition. The primer composition can be applied in a liquid form by a variety of application processes, such as spin coating, dipping, spraying, spreading, and so on. In some examples, the primer composition can include a thermally curable polymer resin. Examples of the polymer in the primer composition can include epoxy, epoxy-polyester, epoxy-polyamide, polyester, polyurethane, phenolic, epoxy-phenolic, urethane acrylic, acrylic, hydroxyl acrylic, alkyd, or others. In some examples, the one-part primer composition can be devoid of curing agents that can cure the polymer at low temperatures, such as at temperatures up to about 60° C. Some highly reactive curing agents, such as polyisocyanates, can cause some polymers to cure quickly, leading to short pot life. These curing agents may be used in two-part coating compositions. However, in some examples the primer compositions described herein can be one-part compositions, meaning that such curing agents are not present.

Additionally, in some examples the primer composition can be a waterborne composition. The polymer in the primer composition can be in the form of an aqueous emulsion. The primer composition can include a surfactant to help emulsify the polymer in water. In contrast, solvent-borne coatings often include solvents with high solvent power to dissolve polymers in the coating composition. Solvents are also often selected based on their evaporation rates. However, evaporation of such solvents creates large amounts of organic fumes that can be harmful to the environment and to the health of workers. Waterborne primer compositions can therefore be safer than solvent-borne compositions.

In some examples, the thermally curable polymer resin can be included in an amount from about 10 wt % to about 30 wt % based on the total weight of the primer composition. The primer composition can also include water in an amount from about 50 wt % to about 75 wt %, an organic co-solvent in an amount from about 10 wt % to about 20 wt %, and a surfactant in an amount from about 0.3 wt % to about 3 wt %. If the primer composition includes a pigment, then the pigment can be present in an amount from about 0.3 wt % to about 10 wt %.

After applying the polymer, the polymer can be cured by heating at a curing temperature for a period of time. In some examples, the curing temperature can be from about 60° C. to about 150° C. In further examples, the curing temperature can be from about 60° C. to about 70° C. or from about 70° C. to about 80° C., or from about 80° C. to about 150° C. The primer layer can be heated at the curing temperature for a curing time. In some examples, the curing time can be from about 3 minutes to about 40 minutes, or from about 3 minutes to about 30 minutes, or from about 15 minutes to about 40 minutes, or from about 3 minutes to about 15 minutes. The thickness of the primer layer can be from about 5 μm to about 30 μm, or from about 5 μm to about 20 μm, or from about 10 μm to about 30 μm, or from about 15 μm to about 20 μm.

### Base Coating Layers

In some examples, a base coat layer can be applied over the substrate. In some examples, the base coat layer can be applied over a primer layer on the substrate. In other examples, the base coat layer can be applied directly to the substrate without a primer layer. The base coat layer can be applied by similar coating processes as the primer layer, such as spin coating, dipping, spraying, spreading, and so on.

The base coat layer can include a filler dispersed in a polymeric resin. In some examples, the filler used in the base coat can be a solid particulate material such as carbon black, titanium dioxide, clay, mica, talc, barium sulfate, calcium carbonate, synthetic pigment, metallic powder, aluminum oxide, organic powder, inorganic powder, plastic beads, and color pigments. In certain examples, the base coat layer can also include a dye. The polymeric resin can be a liquid resin that can include monomers that polymerize to form a polymer, and/or already polymerized polymers that can cure to form a solid polymer layer. Some examples of polymers that can be included in the polymeric resin include polyester, polyacrylic, polyurethane, urethane acrylic, hydroxyl acrylic, alkyd, polyester-imide, epoxy-polyamide, and others. In some examples, the thermally curable polymer resin can be included in an amount from about 10 wt % to about 30 wt % based on the total weight of the basecoat composition. In some examples, the polymer can be in the form of an aqueous emulsion. The basecoat composition can include a surfactant to help emulsify the polymer. The basecoat composition can also include water in an amount from about 50 wt % to about 75 wt %, an organic co-solvent in an amount from about 10 wt % to about 20 wt %, and a surfactant in an amount from about 0.3 wt % to about 3 wt %, and the pigment (filler) in an amount from about 0.3 wt % to about 10 wt %. The basecoat composition can also be a one-part composition, meaning that no separate curing agent is added before applying the basecoat composition. Accordingly, the basecoat composition can be devoid of curing agent in some examples.

In various examples, the thickness of the base coat layer can be from about 10 μm to about 25 μm. In other examples, the thickness can be from about 10 μm to about 15 μm or from about 15 μm to about 25 μm.

After applying the filler and polymeric resin mixture, the layer can be cured. In some examples, the layer can be cured by heating to a temperature from about 60° C. to about 160° C. In other examples, the curing temperature can be from about 60° C. to about 80° C., or from about 80° C. to about 150° C., or from about 120° C. to about 160° C. The layer can be heated at the curing temperature for a curing time. In some examples, the curing time can be from about 3 minutes to about 40 minutes, or from about 3 minutes to about 30 minutes, or from about 15 minutes to about 40 minutes.

### Anti-Fingerprint Topcoat Layers

An anti-fingerprint topcoat layer can be applied over the basecoat layer. The anti-fingerprint layer can include another thermally cured polymer and an anti-fingerprint material. Anti-fingerprint materials can include materials such as silanes, fluorinated polymers, and hydrophobic polymers. A specific example silane is hexadecyl trimethoxy silane. In specific examples, the anti-fingerprint material can include a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof. In certain examples, fluorotelomers can be C-6 or lower in size. In other examples, the anti-fingerprint material can be a hydrophobic polymer that is C-7 or greater in size. In further examples, the thermally curable polymer in the anti-fingerprint topcoat layer can include a polyacrylic, a polyurethane, a urethane acrylic, hydroxyl acrylic, alkyd, polyester, acrylate ester, epoxy acrylate, or a combination thereof. In some examples, the mixture can include the anti-fingerprint material in an amount of about 0.1 wt % to about 5 wt %, or about 0.3 wt % to about 4 wt %, or about 0.5 wt % to about 3 wt %. In some examples, the thermally curable polymer resin can be included in an amount from about 10 wt % to about 30 wt % based on the total weight of the topcoat composition. The topcoat composition can be waterborne, and the polymer can be in the form of an aqueous emulsion in some examples. A surfactant can be included to help emulsify the polymer. The topcoat composition can also include water in an amount from about 50 wt % to about 75 wt %, an organic co-solvent in an amount from about 10 wt % to about 20 wt %, and a surfactant in an amount from about 0.1 wt % to about 2 wt %. In some examples the anti-fingerprint topcoat composition can also include a matting compound such as silica nanoparticles, titania nanoparticles, alumina nanoparticles, or combinations thereof. In certain examples, the matting compound can be present in an amount up to about 3 wt % based on the total weight of the topcoat composition. The topcoat composition can also be a one-part composition. Therefore, the topcoat composition can be free of curing agent in some examples.

The mixture of the anti-fingerprint material, thermally curable resin, and other materials can be applied to the surface of the coated substrate by a variety of application processes, such as spin coating, dipping, spraying, spreading, and so on. The composition can then be cured by heating. In certain examples, the composition can be baked at a temperature from about 80° C. to about 150° C. for a period of time from about 15 minutes to about 40 minutes.

### Definitions

It is noted that, as used in this specification and the appended claims, the singular forms “a,” “an,” and “the” include plural referents unless the content clearly dictates otherwise.

As used herein, the term “about” is used to provide flexibility to a numerical range endpoint by providing that a given value may be “a little above” or “a little below” the endpoint. The degree of flexibility of this term can depend on the particular variable based on experience and the associated description herein.

As used herein, a plurality of items, structural elements, compositional elements, and/or materials may be presented in a common list for convenience. However, these lists should be construed as though individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, but also all the individual numerical values or sub-ranges encompassed within that range as if individual numerical values and sub-ranges are explicitly recited. For example, an atomic ratio range of about 1 at % to about 20 at % should be interpreted to include the explicitly recited limits of about 1 at % and about 20 at %, but also to include individual atomic percentages such as 2 at %, 11 at %, 14 at %, and sub-ranges such as 10 at % to 20 at %, 5 at % to 15 at %, etc.

The terms, descriptions, and figures used herein are set forth by way of illustration and are not meant as limitations. Many variations are possible within the disclosure, which is intended to be defined by the following claims—and equivalents—in which all terms are meant in the broadest reasonable sense unless otherwise indicated.

### Examples

The following illustrates examples of the present disclosure. However, it is to be understood that the following are merely illustrative of the application of the principles of the present disclosure. Numerous modifications and alternative devices, methods, and systems may be devised without departing from the spirit and scope of the present disclosure. The appended claims are intended to cover such modifications and arrangements.

### Example 1—Coated Metal Substrate with Micro-Arc Oxidation Treatment

An example coated substrate for an electronic device is made using the following process. A substrate is made from magnesium alloy by CNC milling, forging, stamping, or thixomolding. A micro-arc oxidation layer is formed on the substrate by submerging the substrate in a bath of 0.3 wt % to 15 wt % of a micro-arc oxidation chemical in water, and then applying a voltage of 150 V to 550 V for a time of 3 minutes to 25 minutes. The micro-arc oxidation chemical is sodium silicate, metal phosphate, potassium fluoride, potassium hydroxide, sodium hydroxide, fluorozirconate, sodium hexametaphosphate, sodium fluoride, ferric ammonium oxalate, phosphoric acid salt, graphite powder, silicon dioxide powder, aluminum oxide powder, metal powder, or a combination thereof. The temperature of the bath is from 10° C. to 45° C. and the pH of the bath is from 8 to 13.

A primer composition is applied onto the micro-arc oxidation layer on the substrate. The primer composition includes 10 wt % to 30 wt % of a thermally curable resin as described above, 50 wt % to 75 wt % water, 10 wt % to 20 wt % organic co-solvent, and 0.3 wt % to 3 wt % surfactant. The primer composition is then cured by heating to a temperature from 80° C. to 150° C. for 3 minutes to 20 minutes.

A basecoat composition is applied over the primer layer. The basecoat composition includes another thermally curable resin that may be the same as or different from the thermally curable resin in the primer layer. The basecoat composition includes the thermally curable resin in an amount from 10 wt % to 30 wt %, and 50 wt % to 75 wt % water, 10 wt % to 20 wt % organic co-solvent, 0.3 wt % to 10 wt % pigment, and 0.3 wt % to 3 wt % surfactant. The basecoat composition is then cured by heating to a temperature from 80° C. to 150° C. for 3 minutes to 20 minutes.

An anti-fingerprint topcoat composition is applied over the basecoat layer. The topcoat composition also includes a thermally curable polymeric resin that may be the same as or different from the polymeric resins in the primer and the basecoat layers. The topcoat composition includes the polymeric resin in an amount from 10 wt % to 30 wt %, and 0.1 wt % to 5 wt % of an anti-fingerprint material such as fluoropolymer or silanes, 50 wt % to 75 wt % water, 10 wt % to 20 wt % organic co-solvent, 0 wt % to 3 wt % matting compound, and 0.1 wt % to 2 wt % surfactant. The anti-fingerprint topcoat composition is cured by heating to 80° C. to 150° C. for 15 minutes to 40 minutes.

The resulting coated substrate has a pencil hardness from 2H to 4H and a water contact angle from 95° to 1100.

### Example 2—Coated Metal Substrate with Passivation Treatment

Another example coated substrate for an electronic device is made using the following process. A substrate is made from magnesium alloy by CNC milling, forging, stamping, or thixomolding. A passivation layer is formed on the substrate by immersing the substrate in an aqueous solution of a passivation chemical, wherein the passivation chemical includes molybdates, vanadates, phosphates, chromates, stannates, manganese salts, or a combination thereof. The concentration of the passivation chemical is from about 3 wt % to about 15 wt %. The substrate is immersed for about 30 seconds to about 180 seconds to form a passivation layer having a thickness of about 1 μm to about 5 μm.

A primer composition is applied onto the passivation layer on the substrate. The primer composition includes 10 wt % to 30 wt % of a thermally curable resin as described above, 50 wt % to 75 wt % water, 10 wt % to 20 wt % organic co-solvent, and 0.3 wt % to 3 wt % surfactant. The primer composition is then cured by heating to a temperature from 80° C. to 150° C. for 3 minutes to 20 minutes.

A basecoat composition is applied over the primer layer. The basecoat composition includes another thermally curable resin that may be the same as or different from the thermally curable resin in the primer layer. The basecoat composition includes the thermally curable resin in an amount from 10 wt % to 30 wt %, and 50 wt % to 75 wt % water, 10 wt % to 20 wt % organic co-solvent, 0.3 wt % to 10 wt % pigment, and 0.3 wt % to 3 wt % surfactant. The basecoat composition is then cured by heating to a temperature from 80° C. to 150° C. for 3 minutes to 20 minutes.

An anti-fingerprint topcoat composition is applied over the basecoat layer. The topcoat composition also includes a thermally curable polymeric resin that may be the same as or different from the polymeric resins in the primer and the basecoat layers. The topcoat composition includes the polymeric resin in an amount from 10 wt % to 30 wt %, and 0.1 wt % to 5 wt % of an anti-fingerprint material such as fluoropolymer or silanes, 50 wt % to 75 wt % water, 10 wt % to 20 wt % organic co-solvent, 0 wt % to 3 wt % matting compound, and 0.1 wt % to 2 wt % surfactant. The anti-fingerprint topcoat composition is cured by heating to 80° C. to 150° C. for 15 minutes to 40 minutes.

The resulting coated substrate has a pencil hardness from 2H to 4H and a water contact angle from 95° to 110°.

### Example 3—Coated Metal Substrate with Powder Coat

Another example coated substrate for an electronic device is made using the following process. A substrate is made from magnesium alloy by CNC milling, forging, stamping, or thixomolding. A passivation layer is formed on the substrate by immersing the substrate in an aqueous solution of a passivation chemical, wherein the passivation chemical includes molybdates, vanadates, phosphates, chromates, stannates, manganese salts, or a combination thereof. The concentration of the passivation chemical is from about 3 wt % to about 15 wt %. The substrate is immersed for about 30 seconds to about 180 seconds to form a passivation layer having a thickness of about 1 μm to about 5 μm.

A powder coat is formed over the passivation layer by applying a high aspect ratio filler such as talc, clay, graphene, or high aspect ratio pigment with a binder such as epoxy, poly(vinyl chloride), polyamide, polyester, polyurethane, acrylic, or polyphenylene ether. These materials are applied to the surface of the passivation layer using an electrostatic application process. The powder coat is then cured by heating at a temperature from about 120° C. to about 190° C. The thickness of the powder coat is from about 20 μm to about 60 μm.

A primer composition is applied onto the powder coat layer on the substrate. The primer composition includes 10 wt % to 30 wt % of a thermally curable resin as described above, 50 wt % to 75 wt % water, 10 wt % to 20 wt % organic co-solvent, and 0.3 wt % to 3 wt % surfactant. The primer composition is then cured by heating to a temperature from 80° C. to 150° C. for 3 minutes to 20 minutes.

A basecoat composition is applied over the primer layer. The basecoat composition includes another thermally curable resin that may be the same as or different from the thermally curable resin in the primer layer. The basecoat composition includes the thermally curable resin in an amount from 10 wt % to 30 wt %, and 50 wt % to 75 wt % water, 10 wt % to 20 wt % organic co-solvent, 0.3 wt % to 10 wt % pigment, and 0.3 wt % to 3 wt % surfactant. The basecoat composition is then cured by heating to a temperature from 80° C. to 150° C. for 3 minutes to 20 minutes.

An anti-fingerprint topcoat composition is applied over the basecoat layer. The topcoat composition also includes a thermally curable polymeric resin that may be the same as or different from the polymeric resins in the primer and the basecoat layers. The topcoat composition includes the polymeric resin in an amount from 10 wt % to 30 wt %, and 0.1 wt % to 5 wt % of an anti-fingerprint material such as fluoropolymer or silanes, 50 wt % to 75 wt % water, 10 wt % to 20 wt % organic co-solvent, 0 wt % to 3 wt % matting compound, and 0.1 wt % to 2 wt % surfactant. The anti-fingerprint topcoat composition is cured by heating to 80° C. to 150° C. for 15 minutes to 40 minutes.

The resulting coated substrate has a pencil hardness from 2H to 4H and a water contact angle from 95° to 110°.

What is claimed is:

1. A coated substrate for an electronic device comprising:
a substrate comprising a metal or metal alloy;
a basecoat layer on the substrate, wherein the basecoat layer comprises pigment particles and a first one-part thermally cured polymeric resin;
an anti-fingerprint topcoat layer on the basecoat layer, wherein the anti-fingerprint topcoat layer comprises a second one-part thermally cured polymeric resin and an anti-fingerprint material comprising a fluoropolymer, a silane, or a combination thereof, and wherein the basecoat layer is cured before applying the anti-fingerprint topcoat layer on the basecoat layer.

2. The coated substrate of claim 1, wherein the metal or metal alloy comprises aluminum, magnesium, lithium, titanium, or an alloy thereof and wherein the substrate includes a passivation layer, a micro-arc oxidation layer, or both on a surface of the substrate.

3. The coated substrate of claim 1, wherein the pigment particles comprise carbon black, graphene, titanium dioxide, clay, mica, barium sulfate, calcium carbonate, metallic powder, aluminum oxide, or a combination thereof.

4. The coated substrate of claim 1, wherein the first one-part thermally cured polymeric resin or the second one-part thermally cured polymeric resin or both comprise urethane acrylic, acrylic, hydroxyl acrylic, alkyd, polyester, or a combination thereof.

5. The coated substrate of claim 1, wherein the anti-fingerprint topcoat layer has a thickness from about 10 μm to about 25 μm.

6. The coated substrate of claim 1, wherein the anti-fingerprint topcoat layer further comprises a matting compound, wherein the matting compound comprises silica nanoparticles, titania nanoparticles, alumina nanoparticles, or a combination thereof.

7. The coated substrate of claim 1, further comprising a primer layer on the substrate and under the basecoat layer, wherein the primer layer comprises a third one-part thermally cured polymeric resin.

8. The coated substrate of claim 7, further comprising a powder coat layer on the substrate and under the primer layer, wherein the powder coat layer comprises:
a polymer comprising epoxy, poly(vinyl chloride), polyamide, polyester,
polyurethane, acrylic, polyphenylene ether, or a combination thereof; and a high aspect ratio filler.

9. The coated substrate of claim 1, wherein a surface of the topcoat layer has a water contact angle from about 95° to about 110°.

10. A method of making a coated substrate for an electronic device comprising:
applying a waterborne one-part basecoat composition on a substrate to form a basecoat layer, wherein the basecoat composition comprises a first thermally curable polymeric resin and pigment particles;
heating the basecoat layer to cure the first thermally curable polymeric resin;
applying a waterborne one-part topcoat composition onto the basecoat layer to form a topcoat layer, wherein the topcoat composition comprises a second thermally curable polymeric resin and an anti-fingerprint material comprising a fluoropolymer, a silane, or a combination thereof; and
heating the topcoat layer to cure the second thermally curable polymeric resin.

11. The method of claim 10, further comprising applying a waterborne one-part primer composition onto the substrate and curing the primer composition to form a primer layer before applying the basecoat composition, wherein the primer composition comprises a third thermally curable polymeric resin.

12. The method of claim 10, wherein the basecoat composition and the topcoat composition have a volatile organic compound content of 200 g/L or less.

13. An electronic device comprising a housing carrying electronic components of the electronic device, wherein the housing includes a coated substrate comprising:
a substrate comprising a metal or metal alloy;
a basecoat layer on the substrate, wherein the basecoat layer comprises pigment particles and a first one-part thermally cured polymeric resin;
an anti-fingerprint topcoat layer on the basecoat layer, wherein the anti-fingerprint topcoat layer comprises a second one-part thermally cured polymeric resin and an anti-fingerprint material comprising a fluoropolymer, a silane, or a combination thereof, and wherein the basecoat layer is cured before applying the anti-fingerprint topcoat layer on the basecoat layer.

14. The electronic device of claim 13, wherein the first one-part thermally cured polymeric resin or the second one-part thermally cured polymeric resin or both comprise urethane acrylic, acrylic, hydroxyl acrylic, alkyd, polyester, or a combination thereof, and wherein the topcoat composition further comprises a matting compound, wherein the matting compound comprises silica nanoparticles, titania nanoparticles, alumina nanoparticles, or a combination thereof.

15. The electronic device of claim 13, wherein the electronic device comprises a display, a personal computer, a laptop computer, a tablet, a media player, a smart device, a keyboard, or a combination thereof.
